(19) United States
(12) Patent Application Publication
(10) Pub. No.: US 2026/0144148 A1
(43) Pub. Date: May 21, 2026

(54) SEMICONDUCTOR PACKAGE

(71) Applicant: Samsung Electronics Co., Ltd., Suwon-si (KR)

(72) Inventor: Injae LEE, Suwon-si (KR)

(73) Assignee: Samsung Electronics Co., Ltd., Suwon-si (KR)

(21) Appl. No.: 19/216,965

(22) Filed: May 23, 2025

(30) Foreign Application Priority Data
Nov. 18, 2024 (KR) 10-2024-0164522

(51) Int. Cl. H01L 23/00; H01L 23/31; H01L 23/538; H01L 25/065; H01L 25/16; H10D 1/68

(52) U.S. Cl. CPC H10W 90/00; H10W 74/117; H10D 1/68; H10W 70/611; H10W 70/65; H10W 72/5473; H10W 72/865; H10W 72/884; H10W 90/20; H10W 90/24; H10W 90/732; H10W 90/734; H10W 90/752; H10W 90/754; H10W 90/759

(57) ABSTRACT

A semiconductor package may include a package substrate, a multilayer ceramic capacitor on the package substrate, a semiconductor device on the package substrate and spaced apart from the multilayer ceramic capacitor in a horizontal direction, and an external wiring on the package substrate and providing an electrical connection path between the multilayer ceramic capacitor and the semiconductor device.

### CROSS-REFERENCE TO RELATED APPLICATION

This application is based on and claims priority under 35 U.S.C. § 119 to Korean Patent Application No. 10-2024-0164522, filed on Nov. 18, 2024, in the Korean Intellectual Property Office, the disclosure of which is incorporated by reference herein in its entirety.

### BACKGROUND

The inventive concepts relate to semiconductor packages, and more particularly, to semiconductor packages including a multilayer ceramic capacitor.

The multilayer ceramic capacitor includes a plurality of laminated dielectric layers, a plurality of internal electrodes arranged opposite each other with the dielectric layers therebetween, and an external electrode electrically connected to the plurality of internal electrodes. Such a multilayer ceramic capacitor is widely used as a component of an electronic device, such as a computer, a mobile phone, and a control module, due to its relatively small size, relatively high capacity, and/or relatively easy mounting. Recently, as electronic devices become smaller and more multifunctional, chip components are also becoming smaller and more functional. Thus, relatively small-sized multilayer ceramic capacitors having relatively large capacity are also in demand.

### SUMMARY

Some example embodiments of the inventive concepts provide semiconductor packages with improved signal characteristics.

In addition, example embodiments of the inventive concepts are not limited to the example embodiments mentioned above. Other example embodiments may be clearly understood by those of ordinary skill in the art from the description below.

According to an example embodiment of the inventive concepts, a semiconductor package includes a package substrate, a multilayer ceramic capacitor on the package substrate, a semiconductor device on the package substrate, the semiconductor device spaced apart from the multilayer ceramic capacitor in a horizontal direction, and an external wiring on the package substrate, the external wiring providing an electrical connection path between the multilayer ceramic capacitor and the semiconductor device.

According to an example embodiment of the inventive concepts, a semiconductor package includes a package substrate including a base layer, a plurality of upper connection pads on an upper surface of the base layer, a plurality of lower connection pads disposed on a lower surface of the base layer, and board wiring electrically connecting some of the plurality of upper connection pads to some of the plurality of lower connection pads, a multilayer ceramic capacitor on the package substrate, a semiconductor device on the package substrate, the semiconductor device spaced apart from the multilayer ceramic capacitor in a horizontal direction, and an external wiring on the package substrate, the external wiring providing an electrical connection path between the multilayer ceramic capacitor and the semiconductor device.

According to an example embodiment of the inventive concepts, a semiconductor package includes a package substrate including a base layer, a plurality of upper connection pads on an upper surface of the base layer, a plurality of lower connection pads on a lower surface of the base layer, and board wiring electrically connecting some of the plurality of upper connection pads to some of the plurality of lower connection pads, a multilayer ceramic capacitor on the package substrate, the multilayer ceramic capacitor including a ceramic body, a first external electrode, a second external electrode, the ceramic body including a plurality of first internal electrodes and a plurality of second internal electrodes alternating with each other with a dielectric layer interposed therebetween, the first external electrode and the second external electrode being at both side edges of the ceramic body, respectively, the first external electrode connected to the plurality of first internal electrodes, the second external electrode connected to the plurality of second internal electrodes, a semiconductor device on the package substrate, the semiconductor device spaced apart from the multilayer ceramic capacitor in a horizontal direction, and an external wiring on the package substrate, the external wiring providing an electrical connection path between the multilayer ceramic capacitor and the semiconductor device, wherein the plurality of upper connection pads include one or more first upper connection pads and one or more second upper connection pads, the one or more first upper connection pads connected to the multilayer ceramic capacitor through a first connection member, the one or more second upper connection pads connected to the semiconductor device through a second connection member.

According to an example embodiment of the inventive concepts, a method manufacturing a semiconductor package includes forming a multilayer ceramic capacitor on a package substrate, mounting a semiconductor device on the package substrate, the semiconductor device spaced apart from the multilayer ceramic capacitor in a horizontal direction, and forming an external wiring on the package substrate, the external wiring providing an electrical connection path between the multilayer ceramic capacitor and the semiconductor device.

The method may further include forming a sealant on the package substrate to surround the multilayer ceramic capacitor, the semiconductor device, and the external wiring.

### BRIEF DESCRIPTION OF THE DRAWINGS

Example embodiments will be more clearly understood from the following detailed description taken in conjunction with the accompanying drawings in which:

FIG. 1 is a cross-sectional view of a semiconductor package including a multilayer ceramic capacitor and a semiconductor chip, according to an example embodiment;

FIG. 2 is a plan view showing a connection relationship of external wiring of the semiconductor package of FIG. 1;

FIG. 3 is a perspective view of the multilayer ceramic capacitor according to an example embodiment;

FIG. 4 is a cross-sectional view taken along line IV-IV′ in FIG. 3;

FIG. 5 is a cross-sectional view of a semiconductor package including a multilayer ceramic capacitor and a semiconductor chip, according to an example embodiment;

FIG. 6 is a plan view showing a connection relationship of external wiring of the semiconductor package of FIG. 5;

FIG. 7 is a cross-sectional view of a semiconductor package including a multilayer ceramic capacitor and a semiconductor chip stack, according to an example embodiment;

FIG. 8 is a plan view showing a connection relationship of wiring of the semiconductor package of FIG. 7;

FIG. 9 is a cross-sectional view of a semiconductor package including a multilayer ceramic capacitor and a semiconductor chip stack, according to an example embodiment;

FIG. 10 is a plan view showing a connection relationship of wiring of the semiconductor package of FIG. 9;

FIG. 11 is a cross-sectional view of a semiconductor package including a multilayer ceramic capacitor and a semiconductor chip stack, according to an example embodiment;

FIG. 12 is a plan view showing a connection relationship of external wiring of the semiconductor package of FIG. 11;

FIG. 13 is a plan view of a semiconductor package including a multilayer ceramic capacitor and a semiconductor chip stack, according to an example embodiment; and

FIG. 14 is a plan view of a semiconductor package including a multilayer ceramic capacitor and a semiconductor chip stack, according to an example embodiment.

### DETAILED DESCRIPTION

Example embodiments are described in detail with reference to the accompanying drawings. The same reference numerals are used for the same components in the drawings, and redundant description thereof are omitted. In the following drawings, the thickness and size of each layer are exaggerated for convenience and clarity of description and thus may be slightly different from the actual shape and proportion.

It should be noted that terms, such as “under”, “below”, “lower”, “above”, “upper” and the like indicating a position in space herein, for the purpose of describing a relative positional relationship between elements or patterns shown in the drawings, are only for ease of understanding and do not limit the inventive concepts in any sense. The terms referring to relative positions in space are intended to encompass variations in the direction of semiconductor devices other than the direction disclosed in the drawings. That is, the semiconductor devices may be oriented in a variety of directions during use (or fabrication). Even in such cases, the positional terms used herein may be easily understood by those of ordinary skill in the art.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

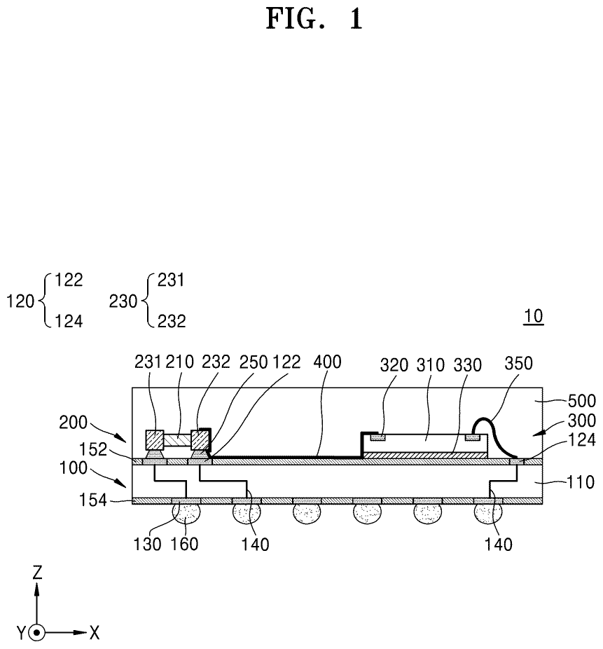

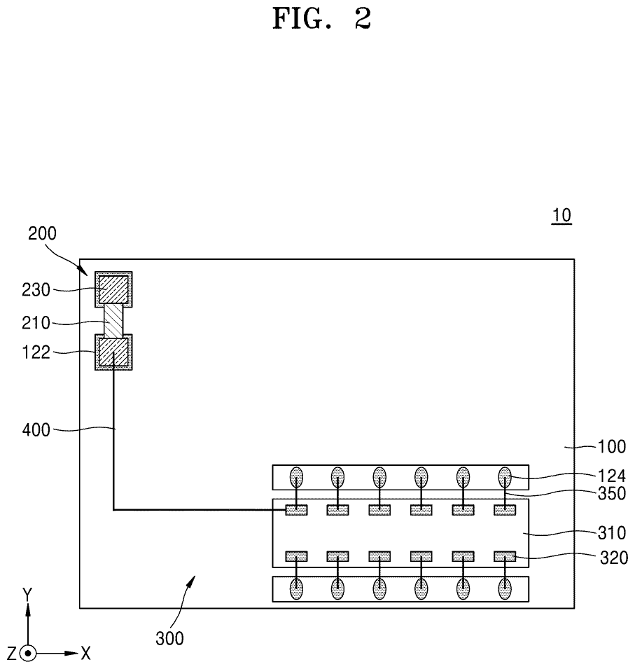

FIG. 1 is a cross-sectional view of a semiconductor package including a multilayer ceramic capacitor and a semiconductor chip, according to an example embodiment. FIG. 2 is a plan view showing a connection relationship of external wiring of the semiconductor package of FIG. 1.

Referring to FIGS. 1 and 2, a semiconductor package 10 may include a package substrate 100, a multilayer ceramic capacitor 200, and a semiconductor chip 300.

The package substrate 100 may include a base layer 110, upper connection pads 120, lower connection pads 130, and board wirings 140. For example, the package substrate 100 may include a printed circuit board. For example, the package substrate 100 may include a multi-layer printed circuit board.

Wirings formed in the base layer 110 may be electrically connected to the multilayer ceramic capacitor 200 through connection terminals. In addition, a port may be arranged in the base layer 110. The base layer 110 may be mounted and electrically connected to a module substrate, a system board, a main board, or the like through the port.

In addition, a body layer may be typically implemented by compressing a polymer material, such as a thermosetting resin, an epoxy-based resin, such as flame retardant 4 (FR-4), bismaleimide triazine (BT), and Ajinomoto build-up film (ABF), or a phenol resin, to a certain thickness to form the same into a thin shape, coating both surfaces thereof with copper foil, and then forming wiring, which is a transmission path for electrical signals, through patterning.

The upper connection pads 120 may be arranged in an upper region of the base layer 110 and the lower connection pads 130 may be arranged in a lower region of the base layer 110. The upper connection pads 120 may be disposed on an upper surface of the body layer and the lower connection pads 130 may be disposed on a lower surface of the body layer. In an example embodiment, at least part of the upper connection pad 120 may be covered by an upper protection layer 152 and at least part of the lower connection pad 130 may be covered by a lower protection layer 154.

The upper connection pads 120 may include first upper connection pads 122 electrically and/or physically connected to the multilayer ceramic capacitor 200 through first connection members 250 and second upper connection pads 124 electrically and/or physical connected to the semiconductor chip 300 through second connection members 350.

External connection terminals 160 may be attached to the lower connection pads 130, respectively. The external connection terminals 160 may be located on lower surfaces of the lower connection pads 130, respectively. The external connection terminals 160 may include a conductive material including, for example, tin (Sn), lead (Pb), silver (Ag), copper (Cu), or a combination thereof. The external connection terminals 160 may be formed, for example, using solder balls. The external connection terminals 160 may connect the semiconductor package 10 to a circuit board, another semiconductor package, an interposer, or a combination thereof.

The package substrate 100 may further include the board wirings 140 electrically connecting at least some of the upper connection pads 120 to at least some of the lower connection pads 130 inside the base layer 110. The board wirings 140 may include board wiring lines and board wiring vias. The board wirings 140 may include Cu nickel (Ni), stainless steel, or beryllium copper (BeCu).

The package substrate 100 may further include the upper protection layer 152 disposed on an upper surface of the base layer 110 and the lower protection layer 154 disposed on a lower surface of the base layer 110. The upper protection layer 152 may cover at least part of the upper surface of the base layer 110 and the lower protection layer 154 may cover at least part of the lower surface of the base layer 110. The upper protection layer 152 may expose at least part of the upper connection pad 120 and the lower protection layer 154 may expose at least part of the lower connection pad 130. The upper protection layer 152 and/or the lower protection layer 154 may include an insulating material. For example, the upper protection layer 152 and/or the lower protection layer 154 may include a solder resist.

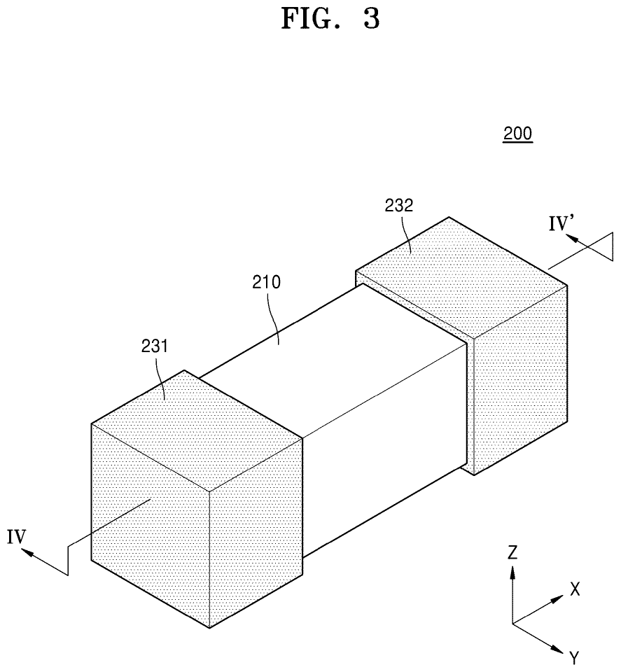

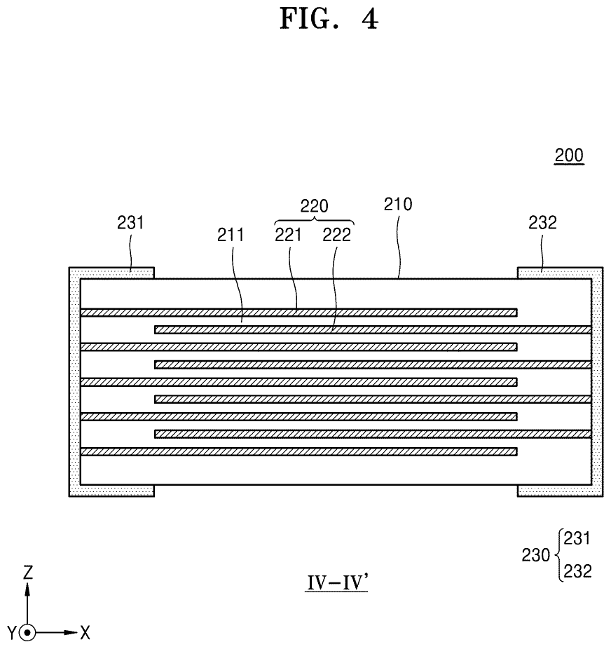

The multilayer ceramic capacitor 200 may be mounted on the package substrate 100. In a plan view, the multilayer ceramic capacitor 200 may be arranged adjacent to an outer region (e.g., at an edge region) of the package substrate 100. The multilayer ceramic capacitor 200 may be electrically and/or physically connected to the package substrate 100 through the first upper connection pads 122. The multilayer ceramic capacitor 200 may be described in detail below with reference to FIGS. 3 and 4.

The multilayer ceramic capacitor 200 may be electrically and/or physically connected to the package substrate 100 through the first connection member 250. For example, the first connection member 250 may be arranged between the external electrode 230 of the multilayer ceramic capacitor 200 and the first upper connection pad 122.

The first connection member 250 may include a solder fillet. For example, the first connection member 250 may include metal. For example, the first connection member 250 may include, but is not limited to, Pb, Ag, Cu, bismuth (Bi), indium (In), zinc (Zn), and/or an alloy thereof.

The semiconductor chip 300 may be mounted on the package substrate 100. The semiconductor chip 300 may be spaced apart from the multilayer ceramic capacitor 200 in a horizontal direction (X direction and/or Y direction), each mounted on the package substrate 100.

In this specification, a direction parallel to a main surface of the package substrate 100 is defined as the horizontal direction (X direction and/or Y direction) and a direction perpendicular to the horizontal direction (X direction and/or Y direction) is defined as a vertical direction (Z direction).

The semiconductor chip 300 may include a logic chip and/or a memory chip. The logic chip may include, for example, a central processing unit (CPU), a graphics processing unit (GPU), or a microprocessor, such as an application processor (AP), an analog device, or a digital signal processor. In addition, the memory chip may include, for example, a volatile memory chip, such as dynamic random-access memory (DRAM) or static RAM (SRAM), or a non-volatile memory chip, such as phase-change RAM (PRAM), magneto-resistive RAM (MRAM), ferroelectric RAM (FeRAM), or resistive RAM (RRAM).

The semiconductor chip 300 may include a semiconductor substrate 310 and semiconductor chip pads 320. The semiconductor substrate 310 may include, for example, silicon (Si). For example, the semiconductor substrate 310 may include a semiconductor element, such as germanium (Ge), or a compound semiconductor, such as silicon carbide (SiC), gallium arsenide (GaAs), indium arsenide, and indium phosphide (InP). For example, the semiconductor substrate 310 may have a silicon-on-insulator (SOI) structure. For example, the semiconductor substrate 310 may include a buried oxide (BOX) layer. The semiconductor substrate 310 may include a conductive region, for example, a well doped with impurities. The semiconductor substrate 310 may have various device isolation structures, such as a shallow trench isolation (STI) structure.

The semiconductor substrate 310 may have an active surface and an inactive surface opposite the active surface. For example, the active surface of the semiconductor substrate 310 may be adjacent to an upper surface of the semiconductor substrate 310 and the inactive surface thereof may include a lower surface of the semiconductor substrate 310.

The semiconductor chip pads 320 may be arranged in an upper region of the semiconductor chip 300. The exposed upper surface of the semiconductor chip 300 may be partially provided with the semiconductor chip pads 320. The semiconductor chip pads 320 may be exposed from a passivation layer provided on the upper surface of the semiconductor chip 300. Some of the semiconductor chip pads 320 may include data pads for transmitting data signals. Some of the semiconductor chip pads 320 may be electrically and/or physically connected to the package substrate 100 through the second connection members 350 and the others of the semiconductor chip pads 320 may be electrically and/or physically connected to the multilayer ceramic capacitor 200 through external wiring 400.

The semiconductor chip 300 may be stacked on the package substrate 100 through the bonding layer 330. The bonding layer 330 may be provided on a lower surface of the semiconductor chip 300. The bonding layer 330 may be provided between the semiconductor chip 300 and the package substrate 100. For example, the bonding layer 330 may include an inorganic adhesive or a polymer adhesive. For example, the polymer adhesive may include a thermosetting polymer or a thermoplastic polymer.

Although FIGS. 1 and 2 show that the semiconductor chip 300 is mounted on the package substrate 100 using a wire bonding method, the inventive concepts are not limited thereto. For example, the semiconductor chip 300 may be mounted on the package substrate 100 using a flip-chip method or other methods.

The semiconductor package 10 may further include the second connection members 350 electrically connecting the package substrate 100 to the semiconductor chip 300. One end of the second connection member 350 may be electrically and/or physically connected to the second upper connection pad 124 of the package substrate 100 and the other end of the second connection member 350 may be physically and/or electrically connected to the semiconductor chip pad 320 of the semiconductor chip 300.

The semiconductor package 10 may further include the external wiring 400 electrically and/or physically connecting the multilayer ceramic capacitor 200 to the semiconductor chip 300 outside the package substrate 100. For example, the external wiring 400 may electrically and/or physically connect the multilayer ceramic capacitor 200 to the semiconductor chip 300 on the package substrate 100. For example, the external wiring 400 may electrically and/or physically connect the multilayer ceramic capacitor 200 to the semiconductor chip 300 on the upper surface of the package substrate 100.

In an example embodiment, the external wiring 400 may be in contact with the multilayer ceramic capacitor 200 and may be in contact with the semiconductor chip 300. For example, the external wiring 400 may be in contact with the external electrode 230 of the multilayer ceramic capacitor 200. For example, the external wiring 400 may be in contact with the first connection member 250. In an example embodiment, the external wiring 400 may be in contact with the semiconductor chip pad 320 of the semiconductor chip 300.

The external wiring 400 may provide a path for directly electrically connecting the multilayer ceramic capacitor 200 to the semiconductor chip 300 on the package substrate 100, thereby improving the electrical characteristics of the semiconductor package 10. For example, on the package substrate 100, the multilayer ceramic capacitor 200 and the semiconductor chip 300 may be electrically connected to each other through the external wiring 400.

The external wiring 400 may provide a path for directly electrically connecting the multilayer ceramic capacitor 200 to the semiconductor chip 300 which are spaced apart from each other in the horizontal direction (X direction and/or Y direction) on the package substrate 100. For example, the multilayer ceramic capacitor 200 and the semiconductor chip 300 may be spaced apart from each other by about 5 mm or more in the horizontal direction (X direction and/or Y direction).

In an example embodiment, the external wiring 400 may be in contact with the first upper connection pad 122. In an example embodiment, the external wiring 400 may be in contact with a power pad of the semiconductor chip 300. The power pad of the semiconductor chip 300 may include a chip pad for providing power and/or ground to the semiconductor chip 300.

In an example embodiment, the external wiring 400 may be formed through a direct printing method. For example, the external wiring 400 may be formed through an inkjet printing method. The inkjet printing method may include spraying a conductive ink to form a desired circuit. However, a method of forming the external wiring 400 is not limited thereto. Various methods may be used.

For example, the external wiring 400 may include a conductive material. For example, the external wiring 400 may include Ag, Cu, carbon nanotubes, graphene, or a combination thereof.

For example, after the multilayer ceramic capacitor 200 and the semiconductor chip 300 are mounted on the package substrate 100, the external wiring 400 may be formed. The external wiring 400 may be formed to be in contact with each of the first upper connection pad 122, the multilayer ceramic capacitor 200, the first connection member 250, and/or the semiconductor chip 300.

In an example embodiment, the external wiring 400 may further include an insulating layer surrounding the external wiring 400. The insulating layer may surround the external wiring 400 to protect the components of the semiconductor package 10.

In an example embodiment, the external wiring 400 may be in contact with the package substrate 100. For example, the external wiring 400 may be in contact with the upper surface of the package substrate 100. For example, the external wiring 400 may be in contact with the upper protection layer 152 of the package substrate 100. As described above, the upper protection layer 152 may include an insulating material. The external wiring 400 may be in contact with the upper protection layer 152 of the package substrate 100 to protect the components of the semiconductor package 10. In another example embodiment, the external wiring 400 may be spaced apart from the upper surface of the package substrate 100 in the vertical direction (Z direction).

In an example embodiment, the external wiring 400 may be in contact with the multilayer ceramic capacitor 200. For example, the external wiring 400 may be in contact with the external electrode 230 of the multilayer ceramic capacitor 200. In another example embodiment, the external wiring 400 may be spaced apart from the multilayer ceramic capacitor 200. In an example embodiment, the external wiring 400 may be in contact with the first upper connection pad 122 and/or the first connection member 250.

The semiconductor package 10 may further include a sealant 500 covering the multilayer ceramic capacitor 200 and the semiconductor chip 300 on the package substrate 100. The sealant 500 may seal the multilayer ceramic capacitor 200 and the semiconductor chip 300 to protect the same from external physical/chemical damage. The sealant 500 may surround the external wiring 400 to protect the components of the semiconductor package 10. A side surface of the sealant 500 may be aligned with a side surface of the package substrate 100 in the vertical direction (Z direction).

The sealant 500 may include an insulating material, for example, a thermosetting resin, such as an epoxy resin, or a thermoplastic resin, such as polyimide. In addition, the sealant 500 may include a resin including a reinforcing material, such as an inorganic filler, in a thermosetting resin or a thermoplastic resin, for example, ABF, FR-4, BT resin, or the like. In addition, the sealant 500 may include a molding material, such as an epoxy molding compound (EMC), or a photosensitive material, such as a photo imageable encapsulant (PIE). For example, the sealant 500 may include the EMC. However, the material of the sealant 500 is not limited to the above-described materials.

The semiconductor package 10 may further include the external wiring 400 electrically directly connecting the multilayer ceramic capacitor 200 to the semiconductor chip 300 on the package substrate 100. The external wiring 400 may provide a path for directly electrically connecting the multilayer ceramic capacitor 200 to the semiconductor chip 300 on the package substrate 100, thereby improving the electrical characteristics of the semiconductor package 10.

FIG. 3 is a perspective view of the multilayer ceramic capacitor according to an example embodiment. FIG. 4 is a cross-sectional view taken along line IV-IV′ in FIG. 3.

Referring to FIGS. 3 and 4, the multilayer ceramic capacitor 200 may include a ceramic body 210 and internal electrodes 220 formed inside the ceramic body 210.

The ceramic body 210 may include an active layer as a portion contributing to capacitance formation of a capacitor, and upper and lower cover layers respectively formed on upper and lower portions of the active layer as upper and lower margin regions, respectively. The active layer may include dielectric layers 211 and the internal electrodes 220.

In an example embodiment, the ceramic body 210 is not limited to a particular shape. However, the ceramic body 210 may substantially have a hexahedral shape. Because there is a difference in thickness due to the presence of the internal electrode pattern and an edge region of the ceramic body 210 is polished, the ceramic body 210 may not have a perfect hexahedral shape but have a shape substantially close to a hexahedron.

When a direction of the hexahedron is defined to clearly describe the inventive concepts, the X direction, the Y direction, and the Z direction shown in the drawings represent a length direction, a width direction, and a thickness direction, respectively. The thickness direction may be used with substantially the same concept as a stacking direction in which the dielectric layers 211 are stacked.

The internal electrodes 220 may include first internal electrodes 221 and second internal electrodes 222, wherein the first internal electrode 222 and the second internal electrode 222 may face each other with the dielectric layer 211 arranged therebetween. The first internal electrode 221 and the second internal electrode 222, which are a pair of electrodes having different polarities, may have a certain thickness on the dielectric layer 211.

In addition, the first internal electrodes 221 and the second internal electrodes 222 may be alternately exposed through both cross-sections of the ceramic body 210 in the stacking direction of the dielectric layers 211 and may be electrically insulated from each other by the dielectric layers 211 arranged therebetween.

That is, the first internal electrodes 221 and the second internal electrodes 222 may be electrically connected to the external electrode 230 through portions alternately exposed through both cross-sections of the ceramic body 210. For example, the external electrode 230 may include a first external electrode 231 and a second external electrode 232. The first internal electrodes 221 may be electrically connected to the first external electrode 231 and the second internal electrodes 222 may be electrically connected to the second external electrode 232.

Therefore, when a voltage is applied to the first external electrode 231 and the second external electrode 232, a charge is accumulated between the first internal electrode 221 and the second internal electrode 222 facing each other. In this case, the capacitance of the multilayer ceramic capacitor 200 is proportional to the area of a region where the first internal electrode 231 overlaps with the second internal electrode 232.

The thicknesses of the first internal electrode 221 and the second internal electrode 222 may be determined depending on example embodiments. The thickness of the dielectric layer 211 may be arbitrarily changed according to the capacity design of the multilayer ceramic capacitor 200. In addition, the first internal electrode 221 and the second internal electrode 222 may include conductive metal, wherein the conductive metal may include, but is not limited to, Ag, Cu, Ni, Sn, gold (Au), or an alloy thereof. For example, the first internal electrode 221 and the second internal electrode 222 may include one or more of palladium (Pd), platinum (Pt), tungsten (W), titanium (Ti), or an alloy thereof.

In addition, for the dielectric layers 211, ceramic powder having a high dielectric constant, for example, a barium titanate-based material, a lead composite perovskite-based material, or a strontium titanate-based material may be used. The barium titanate-based material may include a BaTiO₃-based ceramic powder, for example, (Ba₁₋ₓCaₓ)TiO₃, Ba(Ti_{1-y}Ca_{y})O₃, (Ba₁₋ₓCaₓ)(Ti_{1-y}Zr_{y})O₃, or Ba(Ti_{1-y}Zr_{y})O₃ in which calcium (Ca) or zirconium (Zr) is partially solid-dissolved in BaTiO₃. The material of the dielectric layers 211 may include a powder, such as BaTiO₃, to which various ceramic additives, organic solvents, plasticizers, binders, and/or dispersants may be added according to example embodiments of the inventive concepts.

An uppermost region and a lowermost region of the dielectric layers 211 may include the same material and the same configuration as the other regions of the dielectric layers 211, except that the uppermost region and the lowermost region of the dielectric layers 211 do not include the internal electrodes 220. The uppermost region and the lowermost region of the dielectric layers 211 may be formed by stacking a single dielectric layer or two or more dielectric layers in the up-down direction, thereby reducing or preventing damage to the first internal electrodes 221 and the second internal electrodes 222 due to physical or chemical stress.

As for the external electrode 230, the first external electrode 231 and the second external electrode 232 are directly connected to the first internal electrodes 221 and the second internal electrodes 222, respectively, to ensure electrical continuity between the outside and the inside.

For example, the first external electrodes 231 and the second external electrodes 232 may include conductive metal, wherein the conductive metal may include, but is not limited to, Ni, Cu, Pd, Au, or an alloy thereof. For example, the first external electrodes 231 and the second external electrodes 232 may include one or more of Pt, W, Ti, or an alloy thereof.

Thus, the multilayer ceramic capacitor 200 may include a plurality of stacked dielectric layers 211, a plurality of internal electrodes 220 opposite to each other with the dielectric layer 211 therebetween, and an external electrode 230 electrically connected to the plurality of internal electrodes 220. Such a multilayer ceramic capacitor 200 is widely used as a component of an electronic device, such as a computer, a mobile phone, and a control module, due to its relatively small size, relatively high capacity, and relatively easy mounting.

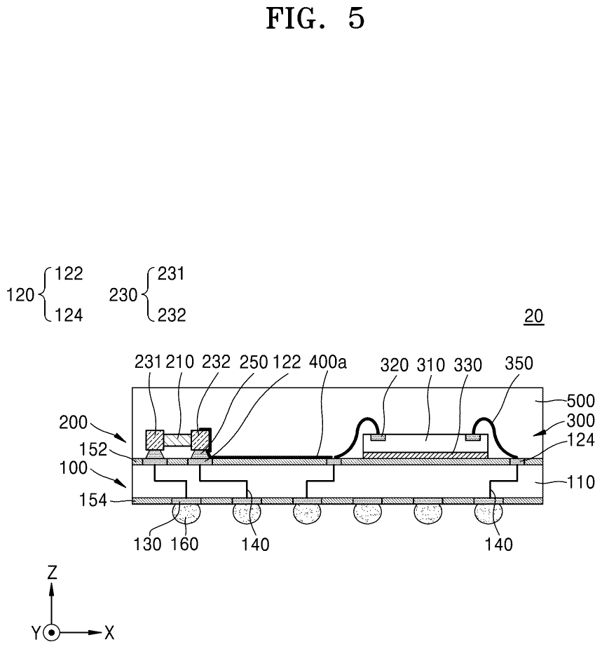

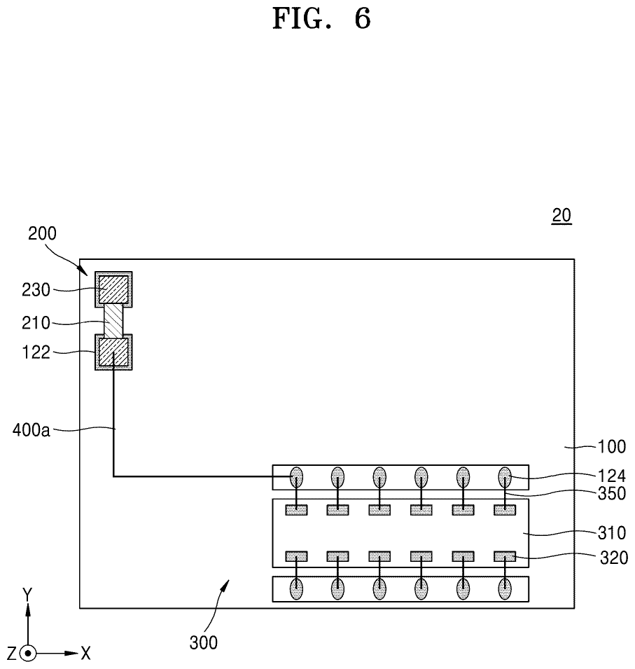

FIG. 5 is a cross-sectional view of a semiconductor package including a multilayer ceramic capacitor and a semiconductor chip, according to an example embodiment. FIG. 6 is a plan view showing a connection relationship of external wiring of the semiconductor package of FIG. 5. The description is made with reference to FIGS. 1 and 2 together.

A semiconductor package 20 of FIGS. 5 and 6 may be the same as or substantially similar to the semiconductor package 10 of FIGS. 1 and 2, except that the semiconductor package 20 includes external wiring 400a. Therefore, the semiconductor package 20 is described focusing on the external wiring 400a.

Referring to FIGS. 5 and 6, the semiconductor package 20 may include a package substrate 100, a multilayer ceramic capacitor 200, a semiconductor chip 300, external wiring 400a, and a sealant 500. The external wiring 400a may provide an electrical connection path between the multilayer ceramic capacitor 200 and the semiconductor chip 300 on the package substrate 100.

In an example embodiment, the external wiring 400a may be in contact with the first upper connection pad 122 of the package substrate 100 and may be in contact with the second upper connection pad 124 of the package substrate 100. The external wiring 400a may provide an electrical connection path between the first upper connection pad 122 and the second upper connection pad 124. In an example embodiment, one end of the external wiring 400a may be in contact with the external electrode 230 of the multilayer ceramic capacitor 200.

As described above, the second upper connection pad 124 may be electrically connected to the semiconductor chip pad 320 of the semiconductor chip 300 through the second connection member 350. That is, the second upper connection pad 124 in contact with the external wiring 400a may include a bond finger. The second connection member 350 may be in contact with the bond finger. On the package substrate 100, the multilayer ceramic capacitor 200 and the semiconductor chip 300 may be electrically connected to each other through the external wiring 400a and the second connection member 350.

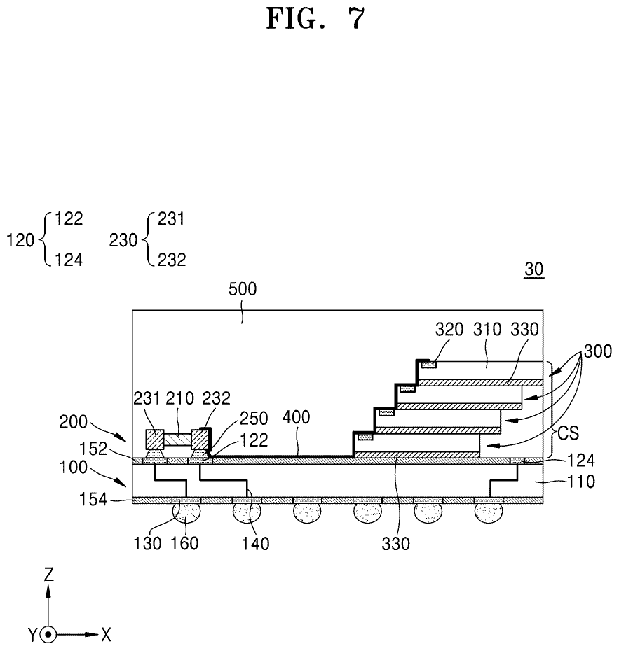

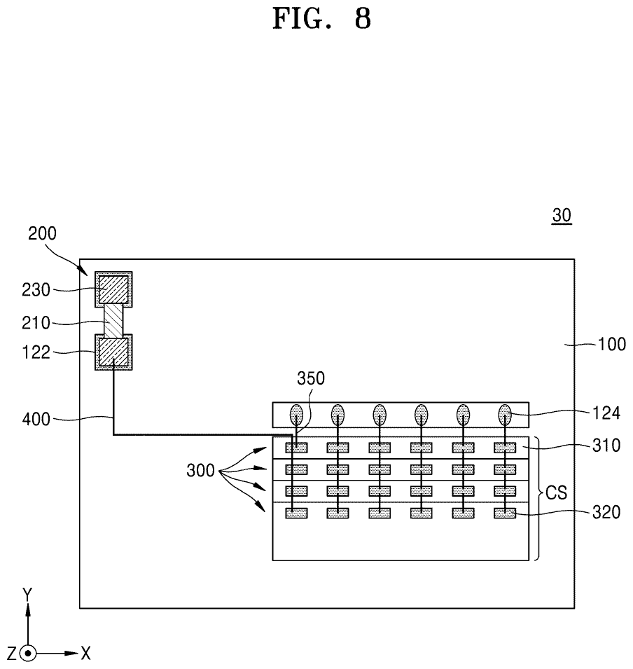

FIG. 7 is a cross-sectional view of a semiconductor package including a multilayer ceramic capacitor and a semiconductor chip stack, according to an example embodiment. FIG. 8 is a plan view showing a connection relationship of wiring of the semiconductor package of FIG. 7. The description is made with reference to FIGS. 1 and 2 together.

A semiconductor package 30 of FIGS. 7 and 8 may be the same as or substantially similar to the semiconductor package 10 of FIGS. 1 and 2 except that the semiconductor package 30 includes a semiconductor chip stack CS instead of the semiconductor chip 300 of FIGS. 1 and 2. Therefore, the semiconductor package 30 is described focusing on the semiconductor chip stack CS.

Referring to FIGS. 7 and 8, the semiconductor package 30 may include a package substrate 100, a multilayer ceramic capacitor 200, a semiconductor chip stack CS, external wiring 400, and a sealant 500. The semiconductor chip stack CS may be mounted on the package substrate 100 and may be spaced apart from the multilayer ceramic capacitor 200 in the horizontal direction (X direction and/or Y direction).

The semiconductor chip stack CS may include one or more semiconductor chips 300. When the semiconductor chip stack CS includes a plurality of semiconductor chips 300, the plurality of semiconductor chips 300 may be stacked in the vertical direction (Z direction). When the semiconductor chip stack CS includes the plurality of semiconductor chips 300, the plurality of semiconductor chips 300 may be stacked in a stepwise manner in the semiconductor chip stack CS. For example, in two semiconductor chips 300 adjacent to each other, an upper semiconductor chip 300 on a lower semiconductor chip 300 may be offset in a specific direction from the lower semiconductor chip 300.

Each of the plurality of semiconductor chips 300 may be stacked on the package substrate 100 and/or the semiconductor chip 300 through the bonding layer 330. The bonding layer 330 may be provided on a lower surface of each of the plurality of semiconductor chips 300. The bonding layer 330 may be provided between adjacent semiconductor chips 300 and/or between the lowermost semiconductor chip 300 and the package substrate 100.

The second connection member 350 may provide an electrical connection path between the plurality of semiconductor chips 300 inside the semiconductor chip stack CS. In addition, the second connection member 350 may provide an electrical connection path between the semiconductor chip stack CS and the second upper connection pad 124.

Although FIGS. 7 and 8 show that the external wiring 400 is electrically and/or physically connected to the semiconductor chip pad 320 of each of the plurality of semiconductor chips 300 of the semiconductor chip stack CS, the inventive concepts are not limited thereto. For example, the external wiring 400 may be electrically and/or physically connected to the semiconductor chip pads 320 of some semiconductor chips 300 of the semiconductor chip stack CS.

In addition, although a single semiconductor chip stack CS is shown in FIGS. 7 and 8, the inventive concepts are not limited thereto. A plurality of semiconductor chip stacks CS may be provided. The plurality of semiconductor chip stacks CS may be stacked in the vertical direction (Z direction) and/or may be spaced apart from each other in the horizontal direction (X direction and/or Y direction).

In addition, instead of the semiconductor chip stack CS, high bandwidth memory (HBM) formed by stacking the plurality of semiconductor chips 300 in the vertical direction (Z direction) may be mounted on the package substrate 100. In addition, a system on chip (SoC) including a plurality of semiconductor chips may be mounted on the package substrate 100 instead of the semiconductor chip stack CS. In addition, the multilayer ceramic capacitor 200 and a plurality of semiconductor devices may be simultaneously mounted on the package substrate 100. That is, semiconductor devices of various structures may be mounted on the package substrate 100, and the external wiring 400 may provide an electrical connection path between the multilayer ceramic capacitor 200 and the semiconductor devices.

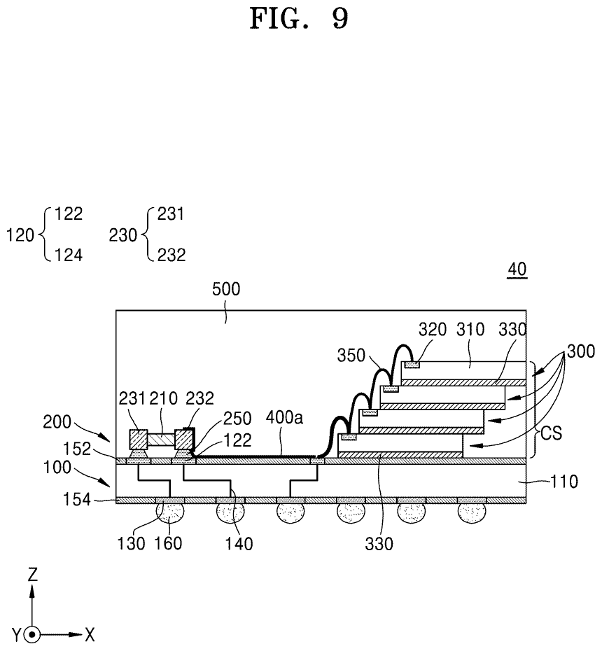

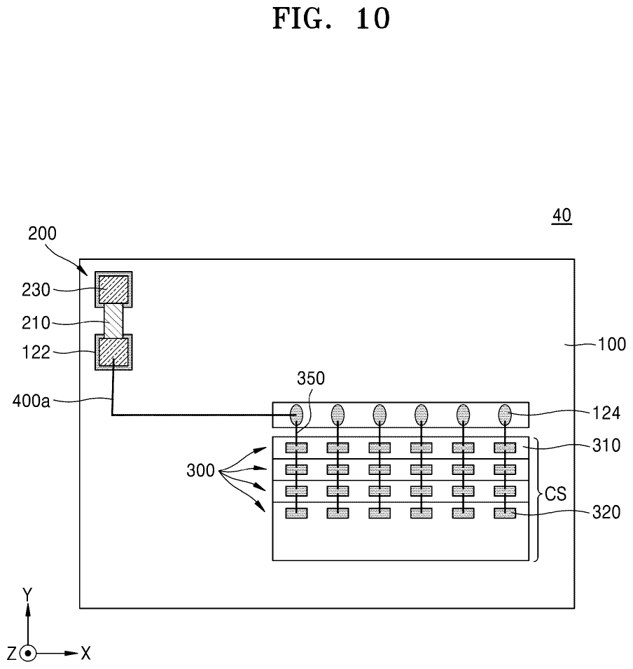

FIG. 9 is a cross-sectional view of a semiconductor package including a multilayer ceramic capacitor and a semiconductor chip stack, according to an example embodiment. FIG. 10 is a plan view showing a connection relationship of external wiring of the semiconductor package of FIG. 9. The description is made with reference to FIGS. 5 and 6 together.

A semiconductor package 40 of FIGS. 9 and 10 may be the same as or substantially similar to the semiconductor package 10 of FIGS. 5 and 6 except that the semiconductor package 40 includes a semiconductor chip stack CS instead of the semiconductor chip 300 of FIG. 5 or 6. Therefore, the semiconductor package 40 is described focusing on the semiconductor chip stack CS.

Referring to FIGS. 9 and 10, the semiconductor package 40 may include a package substrate 100, a multilayer ceramic capacitor 200, a semiconductor chip stack CS, external wiring 400a, and a sealant 500. The semiconductor chip stack CS may be mounted on the package substrate 100 and may be spaced apart from the multilayer ceramic capacitor 200 in the horizontal direction (X direction and/or Y direction). The external wiring 400a may provide an electrical connection path between the multilayer ceramic capacitor 200 and the semiconductor chip stack CS on the package substrate 100.

In an example embodiment, the external wiring 400a may be in contact with the first upper connection pad 122 of the package substrate 100 and may be in contact with the second upper connection pad 124 of the package substrate 100. The external wiring 400a may provide an electrical connection path between the first upper connection pad 122 and the second upper connection pad 124. In an example embodiment, one end of the external wiring 400a may be in contact with the external electrode 230 of the multilayer ceramic capacitor 200.

As described above, the second upper connection pad 124 may be electrically connected to the semiconductor chip pad 320 of the semiconductor chip 300 of the semiconductor chip stack CS through the second connection member 350. That is, the second upper connection pad 124 in contact with the external wiring 400a may include a bond finger. The second connection member 350 may be in contact with the bond finger. On the package substrate 100, the multilayer ceramic capacitor 200 and the semiconductor chip stack CS may be electrically connected to each other through the external wiring 400a and the second connection member 350. The second connection member 350 may provide an electrical connection path between the plurality of semiconductor chips 300 inside the semiconductor chip stack CS. In addition, the second connection member 350 may provide an electrical connection path between the semiconductor chip stack CS and the second upper connection pad 124.

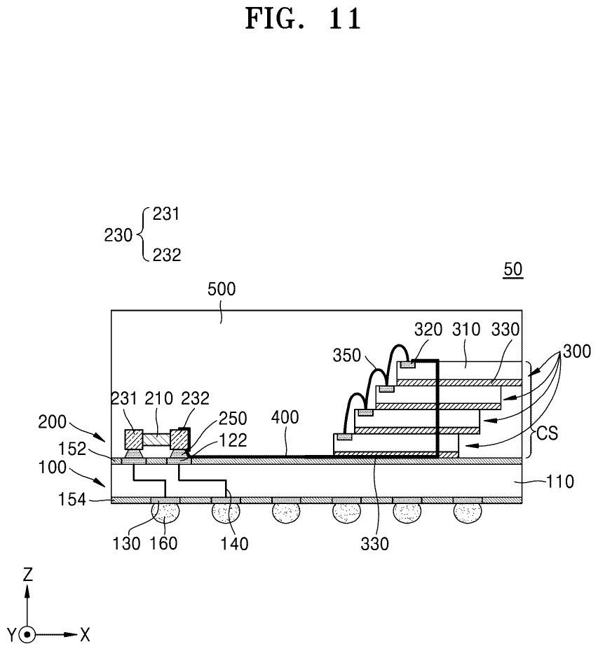

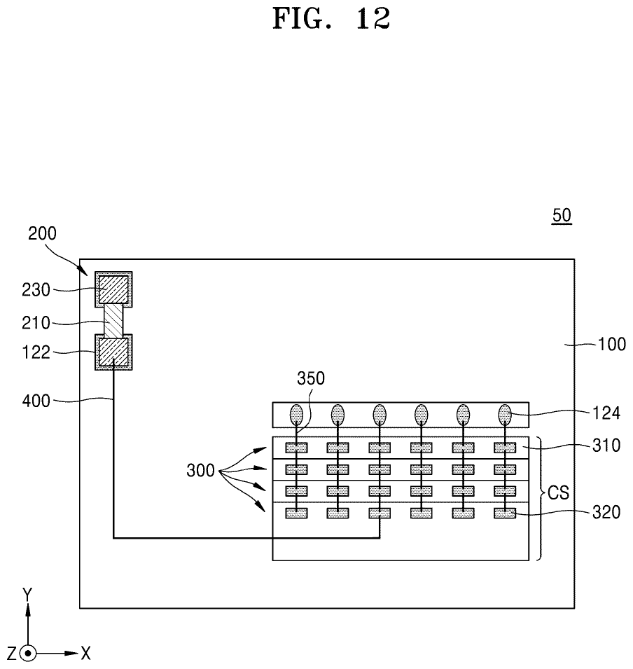

FIG. 11 is a cross-sectional view of a semiconductor package including a multilayer ceramic capacitor and a semiconductor chip stack, according to an example embodiment. FIG. 12 is a plan view showing a connection relationship of external wiring of the semiconductor package of FIG. 11.

A semiconductor package 50 of FIGS. 11 and 12 may be the same as or substantially similar to the semiconductor package 30 of FIGS. 7 and 8 except that the external wiring 400 is connected to the semiconductor chip pad 320 of the uppermost semiconductor chip 300 of the semiconductor chip stack CS. Therefore, the semiconductor package 50 is described focusing on the second connection member 350 and the external wiring 400.

Referring to FIGS. 11 and 12, the semiconductor package 50 may include a package substrate 100, a multilayer ceramic capacitor 200, a semiconductor chip stack CS, external wiring 400, and a sealant 500. The external wiring 400 may be in contact with the semiconductor chip pad 320 of the uppermost semiconductor chip 300 of the semiconductor chip stack CS. The external wiring 400 may be in contact with a side surface of the semiconductor chip stack CS. The second connection member 350 may provide an electrical connection path between the plurality of semiconductor chips 300 inside the semiconductor chip stack CS. In addition, the second connection member 350 may provide an electrical connection path between the semiconductor chip stack CS and the second upper connection pad 124.

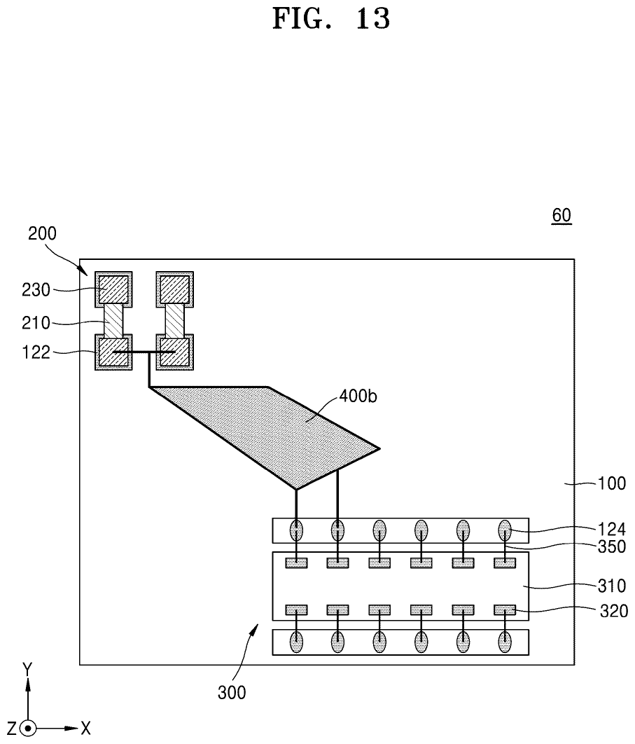

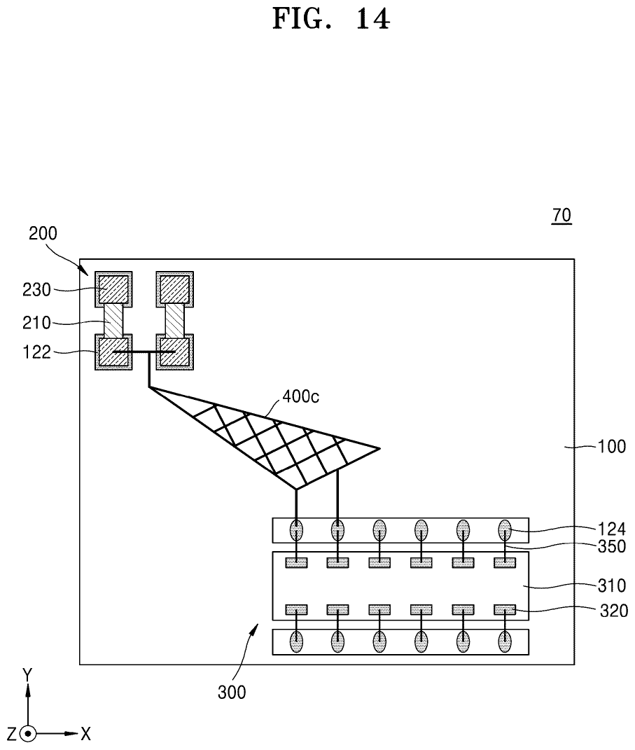

FIGS. 13 and 14 are plan views of a semiconductor package including a multilayer ceramic capacitor and a semiconductor chip stack, according to an example embodiment. The description is made with reference to FIGS. 1, 2, 5, and 6 together.

A semiconductor package 60 of FIG. 13 may be the same as or substantially similar to the semiconductor package 10 of FIGS. 1 and 2, except that the semiconductor package 60 includes external wiring 400b. In addition, a semiconductor package 70 of FIG. 14 may be the same as or substantially similar to the semiconductor package 20 of FIGS. 5 and 6, except that the semiconductor package 70 includes external wiring 400c. Accordingly, the semiconductor packages 60 and 70 are described focusing on the external wirings 400b and 400c. In addition, the sealant 500 is omitted in FIGS. 13 and 14 for convenience of description.

Referring to FIG. 13, the semiconductor package 60 may include a package substrate 100, a multilayer ceramic capacitor 200, a semiconductor chip 300, and external wiring 400b. Referring to FIG. 14, the semiconductor package 70 may include a package substrate 100, a multilayer ceramic capacitor 200, a semiconductor chip 300, and external wiring 400c.

The external wiring 400b of FIG. 13 may have a plane shape and the external wiring 400c of FIG. 14 may have a mesh shape. When the external wiring 400b has a plane shape and/or the external wiring 400c has a mesh shape, the electrical characteristics of the external wirings 400b and 400c may be improved.

For example, when the external wiring 400b has a plane shape and/or the external wiring 400c has a mesh shape, the current capacity of the external wirings 400b and 400c may be increased, the power distribution of the semiconductor packages 60 and 70 may be stabilized, the noise of the external wirings 400b and 400c may be reduced, the heat dissipation in the external wirings 400b and 400c may be improved, and/or impedance of the external wirings 400b and 400c may be easily controlled.

The external wirings 400b and 400c may be in contact with the second upper connection pad 124. As described above, the second upper connection pad 124 may be electrically connected to the semiconductor chip pad 320 of the semiconductor chip 300 through the second connection member 350. That is, the second upper connection pad 124 in contact with the external wirings 400b and 400c may include a bond finger. The second connection member 350 may be in contact with the bond finger. On the package substrate 100, the multilayer ceramic capacitor 200 and the semiconductor chip 300 may be electrically connected to each other through one of the external wirings 400b and 400c and the second connection member 350. The second connection member 350 may provide an electrical connection path between the second upper connection pad 124 and the semiconductor chip 300.

Although FIGS. 13 and 14 show that the external wirings 400b and 400c are electrically and/or physically connected to the two multilayer ceramic capacitors 200, the inventive concepts are not limited thereto. For example, the external wirings 400b and 400c may be electrically and/or physically connected to one multilayer ceramic capacitor 200 or may be electrically and/or physically connected to three or more multilayer ceramic capacitors 200.

In addition, although the external wirings 400b and 400c are shown to be in contact with the second upper connection pad 124 of the semiconductor chip 300 in FIGS. 13 and 14, the inventive concepts are not limited thereto. For example, the external wirings 400b and 400c may be in contact with the semiconductor chip pad 320 of the semiconductor chip 300.

In addition, although not illustrated in FIGS. 13 and 14, a different semiconductor device than the semiconductor chip 300 may be mounted on the package substrate 100. For example, the semiconductor device may include the semiconductor chip stack CS and/or the SoC described with reference to FIGS. 7 and 12.

While the inventive concepts have been particularly shown and described with reference to some example embodiments thereof, it will be understood that various changes in form and details may be made therein without departing from the spirit and scope of the following claims.

What is claimed is:

1. A semiconductor package, comprising:
a package substrate;
a multilayer ceramic capacitor on the package substrate;
a semiconductor device on the package substrate, the semiconductor device spaced apart from the multilayer ceramic capacitor in a horizontal direction; and
an external wiring on the package substrate, the external wiring providing an electrical connection path between the multilayer ceramic capacitor and the semiconductor device.

2. The semiconductor package of claim 1, wherein the external wiring is in contact with at least one of the multilayer ceramic capacitor or the semiconductor device.

3. The semiconductor package of claim 1, wherein the external wiring is in contact with the package substrate.

4. The semiconductor package of claim 1, wherein
the semiconductor device comprises one or more semiconductor chip pads, and
the external wiring is in contact with at least one of the one or more semiconductor chip pads.

5. The semiconductor package of claim 1, wherein the external wiring has at least one of a plane shape or a mesh shape on the package substrate.

6. The semiconductor package of claim 1, further comprising:
a sealant on the package substrate, the sealant surrounding the multilayer ceramic capacitor, the semiconductor device, and the external wiring.

7. The semiconductor package of claim 1, wherein the semiconductor device comprises at least one of a semiconductor chip or a semiconductor chip stack in which a plurality of semiconductor chips are stacked.

8. A semiconductor package, comprising:
a package substrate comprising a base layer, a plurality of upper connection pads on an upper surface of the base layer, a plurality of lower connection pads on a lower surface of the base layer, and board wiring electrically connecting some of the plurality of upper connection pads to some of the plurality of lower connection pads;
a multilayer ceramic capacitor on the package substrate;
a semiconductor device on the package substrate, the semiconductor device spaced apart from the multilayer ceramic capacitor in a horizontal direction; and
an external wiring on the package substrate, the external wiring providing an electrical connection path between the multilayer ceramic capacitor and the semiconductor device.

9. The semiconductor package of claim 8, wherein
the plurality of upper connection pads comprise one or more first upper connection pads connected to the multilayer ceramic capacitor through a first connection member and one or more second upper connection pads connected to the semiconductor device through a second connection member, and
the external wiring is in contact with at least one of the one or more first upper connection pads.

10. The semiconductor package of claim 9, wherein the external wiring is in contact with the first connection member.

11. The semiconductor package of claim 9, wherein the external wiring is in contact with at least one of the one or more second upper connection pads.

12. The semiconductor package of claim 8, wherein the external wiring is in contact with the multilayer ceramic capacitor.

13. The semiconductor package of claim 8, wherein, from a plan view, the multilayer ceramic capacitor is adjacent to an outer region of the package substrate.

14. The semiconductor package of claim 8, wherein a distance between the multilayer ceramic capacitor and the semiconductor device in the horizontal direction is 5 mm or more.

15. The semiconductor package of claim 8, wherein the semiconductor device comprises a memory semiconductor chip.

16. The semiconductor package of claim 8, wherein the external wiring is formed by direct printing.

17. A semiconductor package, comprising:
a package substrate comprising a base layer, a plurality of upper connection pads on an upper surface of the base layer, a plurality of lower connection pads on a lower surface of the base layer, and board wiring electrically connecting some of the plurality of upper connection pads to some of the plurality of lower connection pads;
a multilayer ceramic capacitor on the package substrate, the multilayer ceramic capacitor comprising a ceramic body, a first external electrode, a second external electrode, the ceramic body comprising a plurality of first internal electrodes and a plurality of second internal electrodes alternating with each other, with a dielectric layer interposed therebetween, the first external electrode and the second external electrode being at both side edges of the ceramic body, respectively, the first external electrode connected to the plurality of first internal electrodes, the second external electrode connected to the plurality of second internal electrodes;
a semiconductor device on the package substrate, the semiconductor device spaced apart from the multilayer ceramic capacitor in a horizontal direction; and
an external wiring on the package substrate, the external wiring providing an electrical connection path between the multilayer ceramic capacitor and the semiconductor device,
wherein the plurality of upper connection pads comprise one or more first upper connection pads and one or more second upper connection pads, the one or more first upper connection pads connected to the multilayer ceramic capacitor through a first connection member, the one or more second upper connection pads connected to the semiconductor device through a second connection member.

18. The semiconductor package of claim 17, wherein the external wiring is in contact with the multilayer ceramic capacitor, the first connection member, and at least one of the one or more first upper connection pads.

19. The semiconductor package of claim 17, wherein
the semiconductor device further comprises one or more semiconductor chip pads, and
the external wiring is in contact with at least one of the one or more semiconductor chip pads or at least one of the one or more second upper connection pads.

20. The semiconductor package of claim 17, wherein
the package substrate further comprises an upper protection layer, the upper protection layer covering at least part of an upper surface of the base layer and exposing at least part of some of the plurality of upper connection pads, and
the external wiring is in contact with the upper protection layer.
